(19) United States
(12) Patent Application Publication
(10) Pub. No.: US 2025/0112192 A1
(43) Pub. Date: Apr. 3, 2025

(54) 3D System and Wafer Reconstitution with Mid-layer Interposer based on µbump

(71) Applicant: Apple Inc., Cupertino, CA (US)

(72) Inventors: Sanjay Dabral, Cupertino, CA (US); SivaChandra Jangam, Milpitas, CA (US); Kunzhong Hu, Cupertino, CA (US)

(21) Appl. No.: 18/656,367

(22) Filed: May 6, 2024

Related U.S. Application Data
(60) Provisional application No. 63/586,971, filed on Sep. 29, 2023.

(51) Int. Cl. H01L 23/00; G02B 6/43; H01L 23/15; H01L 23/48; H01L 23/498; H01L 25/16

(52) U.S. Cl. CPC H01L 24/16; G02B 6/43; H01L 23/15; H01L 23/481; H01L 23/49838; H01L 24/13; H01L 25/167; H01L 24/32; H01L 24/73; H01L 2224/13005; H01L 2224/16225; H01L 2224/32225; H01L 2224/73204; H01L 2924/1815

(57) ABSTRACT

A system in package structure and method of fabrication using wafer reconstitution are described. In an embodiment a 3D system includes a mid-layer interposer a first package level underneath the mid-layer interposer and a second package level over the mid-layer interposer. First-level dies and second-level dies can be bonded to the mid-layer interposer with ultra fine micro bumps. Dies within the first and/or second package levels may optionally be connected with one or more optical interconnect paths.

### RELATED APPLICATIONS

This application claims the benefit of priority of U.S. Provisional Application No. 63/586,971, filed Sep. 29, 2023, which is herein incorporated by reference.

### BACKGROUND

### Field

Embodiments described herein relate to semiconductor packaging. More particularly, embodiments relate to three-dimensional (3D) systems and methods of fabrication.

### Background Information

The current market demand for portable and mobile electronic devices such as mobile phones, personal digital assistants (PDAs), digital cameras, portable players, gaming, and other mobile devices requires the integration of more performance and features into increasingly smaller spaces. As a result, various multiple-die packaging solutions such as system in package (SiP) and package on package (PoP) have become more popular to meet the demand for higher die/component density devices.

There are many different possibilities for arranging multiple dies in an SiP. For example, vertical integration of die in SiP structures has evolved into 2.5D solutions and 3D solutions. In 2.5D solutions the multiple dies may be flip chip bonded on an interposer that may include through vias as well as fan out wiring. Various 3D solutions exist. In one implementation multiple dies may be stacked on top of one another on an SiP substrate, and connected with off-chip wire bonds or solder bumps. In other traditional 3D solutions via connected or hybrid bonding using wafer on wafer (WoW) or chip on wafer (CoW) techniques are utilized. In a WoW solution, the top and bottom device area dimensions are exactly matched, and each layer is restricted to one technology node. In such a CoW solution multiple top wafers (chips) can be integrated onto the same bottom wafer with defined area and technology node.

### SUMMARY

Three-dimensional (3D) systems and methods of fabrication are described. In an embodiment, a 3D system includes a mid-layer interposer, a first package level underneath the mid-layer interposer, the first package level including a first-level die bonded to the mid-layer interposer with ultra fine micro bumps (μbumps), and a second package level over the mid-layer interposer, the second package level including a second-level die bonded to the mid-layer interposer with ultra fine μbumps.

### BRIEF DESCRIPTION OF THE DRAWINGS

FIG. 1 is a schematic cross-sectional side view illustration of a multi-chip module (MCM) including a 3D system with mid-layer interposer mounted onto a module substrate in accordance with an embodiment.

FIG. 2 is a schematic cross-sectional side view illustration of an MCM including a monolithic die mounted onto a module substrate.

FIG. 3 is a schematic cross-sectional side view illustration of an MCM including 3D stacked dies mounted onto a module substrate.

FIGS. 4-5 are schematic cross-sectional side view illustrations of 3D systems with mid-layer interposers in accordance with embodiments.

FIG. 6 is a schematic cross-sectional side view illustration of a second package level formed on a partially formed mid-layer interposer in accordance with an embodiment.

FIG. 7 is a schematic cross-sectional side view illustration of a 3D system with mid-layer interposer with removed bulk layer in accordance with embodiments.

FIGS. 8-9 are schematic cross-sectional side view illustrations of 3D systems with mid-layer interposers with a non-encapsulated first package level in accordance with embodiments.

FIG. 10 is a schematic top layout view illustration of a 3D system with die-to-die routing passing through a first-level die in accordance with an embodiment.

FIG. 11 is a schematic cross-sectional side view illustration of a 3D system with a thermal lid in accordance with an embodiment.

FIG. 12 is a schematic cross-sectional side view illustration of a 3D system with a thermal lid on a second-level die in accordance with an embodiment.

FIG. 13 is a schematic cross-sectional side view illustration of a 3D system with a thermally enhanced mid-layer interposer in accordance with an embodiment.

FIG. 14 is a schematic cross-sectional side view illustration of a 3D system with a reconstituted mid-layer interposer including integrated components in accordance with an embodiment.

FIG. 15A is a schematic flow diagram illustrating a repair option process flow in accordance with an embodiment.

FIG. 15B is a schematic cross-sectional side view illustration of a monolithic die set with pre-formed die-to-die routing in accordance with an embodiment.

FIGS. 16-17 are schematic cross-sectional side view illustration of a scribed die set with pre-formed and scribed die-to-die routing mounted on a mid-layer interposer in accordance with an embodiment.

FIGS. 18-23 are schematic cross-sectional side view illustrations of semiconductor package structures with optical interconnects in accordance with embodiments.

FIG. 24 is a schematic cross-sectional side view illustration of a second-level dies including multiple converters and optical vias in accordance with an embodiment.

FIGS. 25A-25B are schematic cross-sectional side view illustrations of a sequence for testing and connecting a bank of deep trench capacitors within a mid-layer interposer in accordance with an embodiment.

FIG. 26 is a schematic cross-sectional side view illustration of a mid-layer interposer with metal-insulator-metal capacitors in accordance with an embodiment.

FIG. 27A is a schematic top view illustration of a via connections to capacitors within a mid-layer interposer in accordance with an embodiment.

FIG. 27B is a schematic top view illustration of landing pad connections to capacitor banks in accordance with an embodiment.

### DETAILED DESCRIPTION

Embodiments describe three-dimensional (3D) systems and multi-chip modules (MCMs) and methods of fabrication in which wafer reconstitution with a mid-layer interposer is used to form 3D systems with ample connectivity between dies and a module substrate, performance (e.g. process node optimization) and power distribution for a scaled 3D system. In particular, the mid-layer interposer in accordance with embodiments can facilitate wafer reconstitution sequences that utilize ultra fine micro bumps (μbumps) for die connectivity. Ultra fine μbumps may provide more manufacturing tolerances and lower cost relative to hybrid bonding, though potentially with slightly coarser pitch, while still providing high pin density and low latency. Ultra fine μbumps may additionally allow for integration of more third-party chips such as dynamic read only memory (DRAM) or other memory, cache, power, compute, amplifiers, optical, compound semiconductor devices, other types of novel material devices like graphene, carbon nano tube (CNT), meta-materials, etc., sub-systems such as artificial intelligence (AI), machine learning (ML), etc. and different types of packages (e.g. sub-modules). The mid-layer interposer may also provide additional routing area, allowing for die partitioning and process node optimization, as well as flexibility for power delivery and integration of passive devices into the 3D system. In an embodiment the 3D system is a three-dimensional integrated circuit (3DIC), system-in-package (SiP), or other system. The mid-layer interposers in accordance with embodiments may be formed of a variety of materials due to the integration with ultra fine μbumps, which provide more surface mount planarity tolerance relative to hybrid bonding, thus expanding the range of materials selection beyond silicon. In this manner material selection, while inclusive of silicon, can extend to other materials that can provide additional properties suitable for the particular 3D systems (or packages), including cost, thermal conductivity, manufacturability, ability to integrate heterogeneous components, etc.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The 3D systems in accordance with embodiments may additionally include electromagnetic field communication structures for wireless communication.

The terms “underneath”, “over”, “to”, “between”, and “on” as used herein may refer to a relative position of one layer with respect to other layers. One layer “underneath”, “over”, or “on” another layer or bonded “to” or in “contact” with another layer may be directly in contact with the other layer or may have one or more intervening layers. One layer “between” layers may be directly in contact with the layers or may have one or more intervening layers.

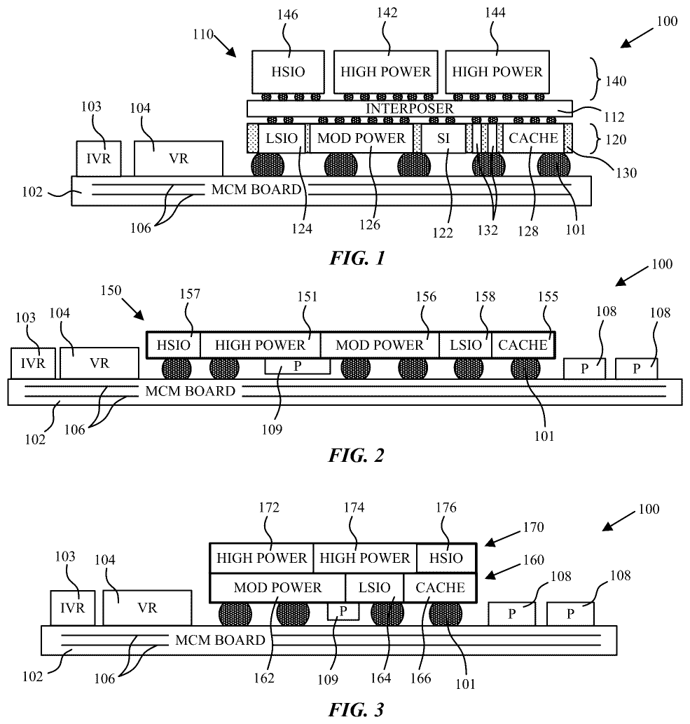

Referring now to FIG. 1 a cross-sectional side view illustration is provided of a multi-chip module (MCM) 100 including a 3D system 110 with mid-layer interposer 112 mounted onto a circuit board 102 in accordance with an embodiment. In an embodiment, a 3D system 110 includes a mid-layer interposer 112, a first package level 120 underneath the mid-layer interposer and a second package level 140 over the mid-layer interposer 112. The first package level 120 may include one or more dies bonded to the interposer 112 with ultra fine μbumps, and the second package level 140 may include at least one logic die hybrid bonded to the mid-layer interposer 112 with ultra fine μbumps. For example, the ultra fine μbump pitch may scale sub 15 μm, sub 10 μm, or even sub 6 μm or lower. The ultra fine μbumps may be solder based, copper-copper polymer based, etc. Vertical interconnection in accordance with embodiments can be achieved using through vias (TVs) 132 that extend through the die(s) (e.g. through silicon vias, through silicon-germanium vias, etc.), through the encapsulation layer 130 material (e.g. through oxide vias or through mold vias), and through the mid-layer interposer 112. Through vias can be formed in a variety of manners and at a variety of different process stages.

A variety of dies/components can be included in the first package level 120. For example, the dies can be a moderate power die 124 (or low power) such as a system-on-chip (SOC), logic, memory, power management integrated circuit (PMIC), etc. Additional dies/components include, but are not limited to, a low speed input/output (LSIO) die 126, cache die 128 (or memory buffer), and silicon interconnect 122. The silicon interconnect 122, for example, can be a chiplet including lateral routing for die-to-die connections. In some embodiments, no logic or passive devices are included in the silicon interconnect 122, and the silicon interconnect is used primarily for fine die-to-die wiring. In other embodiments capacitors or logic can be included within the silicon interconnect 122 in combination with the fine die-to-die wiring (or optical path). In the illustrated embodiments dies included in the second package level 140 can include high speed input/output (HSIO) die 146, and one or more high power dies 142, 144 such as a graphics processing unit (GPU), central processing unit (CPU), artificial intelligence (AI), machine learning logic, radio-frequency (RF) baseband processor, radio-frequency (RF) antenna, signal processors, power management integrated circuit (PMIC), logic, memory, photonics, biochips, silicon interconnect and any combinations thereof. It is to be appreciated that the specific listing and illustration of dies/components in the first and second package levels is exemplary, and embodiments are not limited to these specific examples. In accordance with embodiments the various dies can include an assembly of different components, can be heterogenous, and can be hierarchically arranged. For example, a die may include separately formed layer(s) of an optical converter, or multiple attached components. While the silicon interconnect 122 is described as being a chiplet, any of the dies can be chiplets. Furthermore, any of the dies/chiplets in the first or second package levels may be active components, passive components, or combinations thereof.

The ultra fine μbump 152 size in accordance with embodiments can be adjusted to routing requirement needs, warpage requirements, and the dies or packages being assembled. For example, thicker dies may have the tightest pitches of the ultra fine μbumps 152, whereas a 3D stacked die (or package) may have a more relaxed pitch (e.g. to accommodate more warpage, thermal coefficient of expansion mismatch, etc.) The ultra fine μbumps 152 may be arranged in multiple areas with different corresponding pitches underneath a single die or be arranged with a uniform pitch underneath an entire die. In an embodiment, the dies of the first package level 120 and the second package level 140 do not have the same ultra fine μbump 152 pitch. It is possible that the dies in the first package level 120 have a slightly looser ultra fine μbump 152 pitch to accommodate manufacturing needs, flow (warpage, planarity at that manufacturing stage), cost targets, etc.

As shown, the 3D system 110 (e.g. package) can be mounted onto a circuit board 102 of the multi-chip module 100. Additional components such as one or more voltage regulators 104, high efficiency inductor voltage regulator 103, passives, and other subsystems can be mounted onto the circuit board 102. The voltage regulator 104 may be connected with the 3D system 110 through one or power rails 106 within the circuit board 102 to provide high and low power. The moderate power die 124 for example, may include a control circuit including various switches to close or open high voltage and low voltage channels from the voltage regulator 104. The high efficiency inductor voltage regulator 103 may additionally be connected with the power rails, for example to provide droop assist when the dies are operating in modes with large current change transients.

The mid-layer interposer 112 in accordance with embodiments may be passive and may include an array of passive devices such as capacitors connected to the high voltage and low voltage channels in order to control the voltage output to circuit loads of the various components, including the high power dies 142, 144 or other dies. In this manner, much of the power management for the dies can be integrated into the 3D system 110, and directly underneath the high power dies 142, 144.

In one aspect, it has been observed that traditional 3D wafer reconstitution techniques have limitations for die stacking where bonded dies cannot bridge across different die boundaries such as overlap of bonded dies with two or more die boundaries. These may cause topography differences, leading to voids, non-bonding or other issues. The mid-layer interposer 112 in accordance with embodiments facilitates such die bridging, with high pin (contact pad) densities and low latency. As such, the mid-layer interposer 112 and/or the silicon interconnect 122 can bridge across the high power dies 142, 144. The mid-layer interposer 112 in accordance with embodiments can provide a bonding interface and electrical interconnections only, or include passives such as trench capacitors, or metal-insulator-metal (MIM) capacitors, magnetic elements (inductors, coupled inductors, etc.), or even include active devices. In some embodiments, mid-layer interposer 112 approximately spans the surface area of one or both of first package level 120 and second package level 140. In some embodiments, mid-layer interposer 112 spans a subset of the surface area of first package level 120 and/or spans a subset of the surface area of second package level 140. In some embodiments, at least one lateral dimension of mid-layer interposer 112 extends beyond a corresponding lateral dimension of first package level 120 and/or second package level 140.

In another aspect, embodiments facilitate die partitioning such that process nodes can be optimized for different intellectual property (IP) blocks. In order to illustrate this effect a cross-sectional side view illustration of an MCM including a monolithic die 150 mounted onto a circuit board 102 is shown in FIG. 2. As shown in the exemplary illustration, the various IP blocks (corresponding to high power 151, HSIO 157, cache 155, moderate power 156, LSIO 158 in the example) are formed in a monolithic die, which is formed with the same process node (e.g. transistor size). In this manner, the selected process node may be ideal for some IP blocks but not all. Furthermore, larger dies can be associated with a greater number of likely process failures leading to more expenses associated with die rejects.

In yet another aspect, embodiments facilitate other crucial functions including but not limited to circuit board power distribution to the 3D system. Still referring to FIG. 2, it is shown that such a monolithic die configuration also requires additional circuit board 102 area for passive devices 108, 109. This may also require additional board routing and power rails 106. While necessary circuit board 102 area can be reduced somewhat by locating passive devices 109 underneath the monolithic die 150, this can also have the effect of reducing area for power delivery to the monolithic die 150 and increasing wiring requirements of the monolithic die. It is to be appreciated that while a passive device 109 is shown as being mounted onto an underside of the monolithic die 150 in FIG. 2, that this is also possible with the 3D system 110 of FIG. 1.

Referring now to FIG. 3, a schematic cross-sectional side view illustration of an MCM including 3D stacked dies 160, 170 mounted onto a circuit board 102. The 3D stacked dies may have similar IP blocks (corresponding to moderate power 162, LSIO 164, cache 166, high power 172, high power 174, HSIO 176, respectively, in this example). As shown, the 3D die stacking can reduce overall circuit board area, though power delivery to the 3D die stack can be oversubscribed, with the number of power rails/area impacting voltage droop (IR), electromigration (EM) and AC impedance. Furthermore, the 3D die stacking of FIG. 2, like the monolithic die 150 of FIG. 1, does not facilitate process node optimization for all IP blocks.

Now referring again to FIG. 1, the 3D system 110 in accordance with embodiments and mid-layer interposer 112 can accommodate many attributes, including process node optimization, area reduction, power distribution, and low inductance interconnects. Fundamentally, the mid-layer interposer 112 can provide a prime bonding surface with controlled roughness, particles, and tolerances that allows for ultra fine μbumping at pitches of less than 15 μm. The mid-layer interposer may optionally have additional integrated functionality. In an exemplary embodiment, voltage regulation can be largely integrated within the 3DIC, particularly when capacitors are integrated into the mid-layer interposer 112. Furthermore, wafer sizes used to form the components in the different package levels can be arbitrary, and not yield limiting for the stacked 3D system. The dies/components can be different technologies (IP blocks) and formed with different process nodes (e.g. transistor size, etc.). Vias may be additionally provided through the bottom dies/components to provide power supply, or support with decoupling capacitors, for example.

The mid-layer interposer 112 in accordance with embodiments may have several metal routing layers (e.g. 3-5 metal layers), or may have less metal routing layers (e.g. 1-2 metals layers) to land various through vias and ultra fine μbumps. The ultra fine μbumps in accordance with embodiments may have different pitches across different dies/components and within larger dies/components. Additionally, the ultra fine μbump pitches on the top/bottom sides of the mid-layer interposer may not be at the same pitch so as to either loosen the poorer pitch or provide fanout options. The mid-layer interposer 112 may still include die-to-die routing, or this may be offloaded to a die/chiplet in a same or different package level. Such dies/chiplets can be integrated into either or both package levels, and be chosen to suit function and performance. Similarly, the mid-layer interposer 112 can include active devices (e.g. including logic, etc.), as well as include passive devices (e.g. such as an integrated passive device like capacitor, resistor, inductor, etc.) or passive components such as a waveguide, which can also be coupled to various converters such as optical-to-electrical converters or electrical-to-optical converters.

The mid-layer interposer 112 in accordance with embodiments can additionally include materials with high thermal conductivity for thermal assist of the high performance dies. For example, a composite material or silicon carbide (SiC) can have good coefficient of thermal expansion (CTE) match with silicon, with higher thermal conductivity than silicon. The mid-layer interposer 112 can additionally allow for lower parasitic through vias when formed of a suitable material such as glass or polymer, or composite (e.g. with silicon filler) to tune properties.

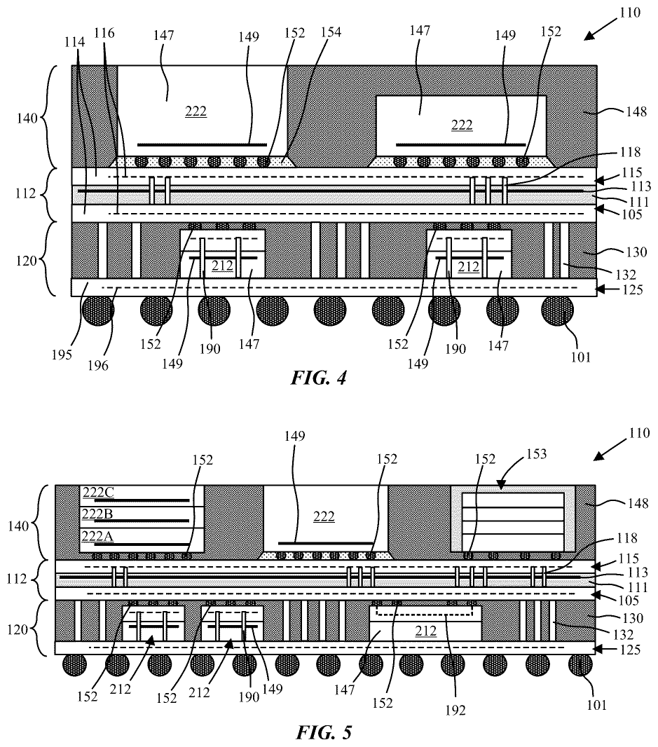

FIG. 4 is a schematic cross-sectional side view illustration of a 3D system 110 with mid-layer interposer 112 in accordance with an embodiment. In particular, FIG. 4 provides additional detail for a 3D system 110 such as the one illustrated in FIG. 1. As shown, the 3D system 110 can include a mid-layer interposer 112, a first package level 120 underneath the mid-layer interposer, and a second package level 140 over the mid-layer interposer. The first package level 120 can include one or more first-level dies 212 (e.g. any of silicon interconnect 122, moderate power die 124 (such as SOC, logic, memory), LSIO die 126, cache die 12 or combination thereof) bonded to the mid-layer interposer 112 with a plurality of ultra fine μbumps 152. Thus, the first-level dies 212 can be bonded face-side up to the mid-layer interposer 112 (such as with landing pads of a back-end-of-the-line (BEOL) build-up structure of the component). Alternatively, any of the first-level dies can be bonded back-side up to the mid-layer interposer 112 (such as with a back side oxide bonding layer on a back side of a silicon bulk layer 147 of the component, or with an adhesive layer). The various first-level dies 212 in the first package level may have the same or different thicknesses. For example, the thinner first-level dies 212 may not have through vias for vertical interconnection.

The second package level 140 can similarly include one or more second-level dies 222 (e.g. any of high power die 142 (e.g. logic die such as GPU or CPU), high power (performance) die 144 (logic die such as GPU or CPU), HSIO die 146, memory die stack 153) bonded to the mid-layer interposer 112 with a plurality of ultra fine μbumps 152. Each first-level die 212 and second-level die 222 can include a BEOL build-up structure. Each BEOL build-up structure may include one or more dielectric layers, metal wiring layers, such as copper, and landing pads to receive the ultra fine μbumps 152. It is to be appreciated that the first-level dies 212 and second-level dies 222 are not limited to these specific examples. The BEOL build-up structures of the various dies may be formed over a silicon bulk layer 147, which may contain a plurality of devices 149 formed in specific process nodes. For example, devices 149 can include transistors for active devices, as well as storage devices such as SRAM/DRAM/MRAM (or other technologies) for cache die. Devices 149 may be also formed within the silicon interconnect die, including both passive (including trench capacitors) and active devices.

In accordance with embodiments the various components in the first and second package levels can be monolithic or stacked dies. For example, memory or other types of components may have stacked dies.

The metal wiring layers of the silicon interconnect may form die-to-die wiring 192 for interconnection between multiple dies. The complete die-to-die routing path may pass through a portion of the set of through vias 118 (and wiring layers within the top side routing layer 115 and/or back side routing layer 105) extending through the mid-layer interposer, and be connected with die-to-die wiring 192. Wiring within the BEOL build up structures may be fabricated using suitable damascene processing for example. One or more of the first-level dies 212 in the first package level 120 may include through vias 190 extending at least from a back side to the BEOL build-up structure thereof. For example, the through vias 190 can be used for power delivery, for example, to the overlying dies.

The mid-layer interposer 112 in accordance with embodiments can include a bulk layer 111 (such as silicon, glass, or dielectric material with high thermal conductivity) and a top side routing layer 115, and optional back side routing layer 105, including one or more dielectric layers 116 and metal wiring layers 114 and landing pads. While not illustrated in detail the various metal wiring layers 114 may be formed using conventional damascene or thin film deposition techniques, and various levels of metal wirings layers can be connected with vias extending through one or more dielectric layers 116 (interlayer dielectrics) between the metal wiring layers. The metal routing layers may additionally be absent with only vias extending through one or more dielectric layers 116, and optional landing pads for receiving ultra fine μbumps.

It is to be appreciated that while embodiments are described with regard a silicon bulk layer 111, this bulk layer may be formed of other non-silicon materials including glass, silicon carbide, other compound semiconductors. Reconstituted interposers including embedded devices are also described. Additionally, the mid-layer interposer 112 may be active or passive. A plurality of through vias 118 (e.g. through silicon vias, through glass vias, through dielectric vias, through mold vias, etc.) can extend through the bulk layer 111 and optionally into either of the top side routing layer 115 and/or back side routing layer 105. The mid-layer interposer 112 may additionally include a plurality of devices 113, including passive devices such as MIM capacitors (planar or 3D) or trench capacitors, magnetic elements (inductors, coupled inductors, etc.), or even active devices such as transistors. In an embodiment, the mid-layer interposer includes an array of trench capacitors.

The dies/components within the second package level 140 may be embedded/encapsulated within an encapsulation layer 148, such as an inorganic encapsulation/fill layer material (e.g. dielectric/oxide or silicon) or organic molding compound layer material (e.g. molding compound material). A silicon encapsulation layer material, or gap fill material, can be used where no vertical interconnections are to be made therethrough. Metals may also be used to facilitate thermal transfer. Likewise, the components within the first package level 120 can be embedded/encapsulated within an encapsulation layer 130, such as an inorganic encapsulation layer material (e.g. oxide, oxynitride, silicon) or organic molding compound layer material. A plurality of through vias 132 (e.g. through dielectric vias) may extend completely through a thickness of the encapsulation layer 130, and laterally adjacent the components, to make electrical connection within the mid-layer interposer 112, such as with the through vias 118 (through silicon vias, through glass vias, etc.). A back-side redistribution layer (RDL) 125 may optionally be formed underneath the encapsulation layer 130. The back-side RDL 125 may include contact pads formed on the through vias 132 and through vias 190. The back-side RDL 125 may include one or more dielectric layers 195 and metal routing layers 196, and landing pads which can receive solder bumps 101. The metal routing layers 196 may be formed using thin film techniques, or alternatively with damascene processing.

Referring now to FIG. 5, a 3D system 110 is illustrated similar to that of FIG. 4 with several variations. Firstly, any of the first-level dies or second-level dies, and in particular the second-level dies 222, may include multiple die stacks, such as active dies 222A, 222B, 22C. The stacked dies 222A, 222B, 222C can be ultra fine μbumped, hybrid bonded, and may be dissimilar technology. A second variation is the memory die stack 153, which shows a second-level dies formed of a die stack rather than a monolithic die. The dies of the memory die stack may be ultra fine μbumped, hybrid bonded, or wire bonded, and may be encapsulated within a molding compound as part of a sub-package. For example, the memory die stack 153 may be high bandwidth memory (HBM) or dynamic random access memory (DRAM). While a memory die stack 153 is illustrated it is understood this is exemplary and components with stacked dies are not limited to memory. Additionally shown is a first-level die 212 (e.g. silicon interconnect) with die-to-die wiring 192. The silicon interconnect may be a chiplet and may be purely passive, or active, and may additionally include passive components such capacitors, inductors, etc. Furthermore, the silicon interconnect may be a monolithic die, or stacked die (stacked chiplet) structure. The mid-layer interposer 112 in accordance with embodiments may facilitate the stacking of complementary metal-oxide-semiconductor (CMOS) or memory dies, along with single CMOS dies (e.g. high performance and thermal limited dies) in the second package level 140. Furthermore, integration of active devices in the mid-layer interposer 112 can be used to aggressively reduce the 3D system 110 (i.e. package) footprint.

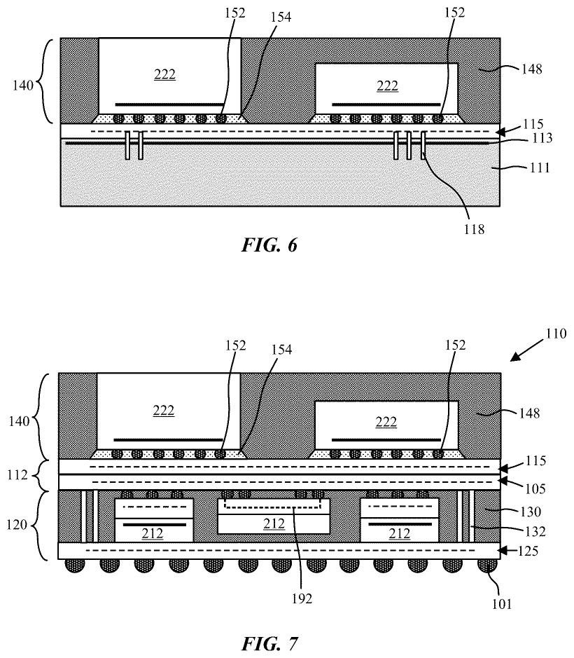

Referring now to FIG. 6, a schematic cross-sectional side view illustration is provided of a second package level 140 formed on a partially formed mid-layer interposer in accordance with an embodiment. It is to be appreciated that at this point, the fabrication sequence may be at the wafer-scale or panel-scale prior to singulation into a plurality of 3D IC systems. Depending upon material, a variety of substrate sizes and shapes can be used not limited to wafer-scale or panel-scale. As shown, the partially formed mid-layer interposer can include a bulk layer 111, such as a bulk silicon substrate, glass, polymer, or material with higher thermal conductivity than silicon such as silicon carbide, etc. A plurality of devices 113 may optionally be formed, along with a top side routing layer 115. A plurality of through vias 118 may be formed prior to, during, or after formation of the top side routing layer 115, and thus may or may not extend into the top side routing layer 115. As shown, it is not required for the plurality of through vias 118 to extend completely through the bulk layer 111, which may be a silicon wafer for example that is later thinned. The through vias 118 can be nano-vias, micro-vias, etc. It is to be appreciated that at this manufacturing stage the assembly is as the wafer-level or panel level, prior to singulation of individual packages, or 3D systems 110. For example, the bulk layers 111 may be wafers (e.g. semiconductor wafers, glass, or other materials), as well as panels such as glass panels, or other materials such as polymer, composite, ceramic, etc. A variety of substrate sizes and shapes can be used, and are not limited to wafer-scale or panel-scale.

The second package level 140 may be formed over the top side routing layer 115 by flip chip mounting of the second-level dies 222 with ultra fine μbumps 152, optional application of underfill material 154 underneath the second-level dies 222 and around the ultra fine μbumps 152, followed by encapsulation with encapsulation layer 148. At this point the structure can be flipped over, followed by thinning of the bulk layer 111 using suitable techniques such as grinding and/or laser lift off to reveal the through vias 118. Referring back to FIGS. 4-5, the back side routing layer 105 may then be optionally formed, followed by mounting of the first-level dies 212, such as with flip chip mounting with ultra fine μbumps 152. This may optionally be followed by encapsulation with encapsulation layer 130, and the formation of through vias 132, which can be copper pillars for example formed prior to the encapsulation layer, or through mold vias formed after the encapsulation layer 130. The back-side RDL 125 can then be optionally formed, followed by optional placement of solder bumps 101, and singulation into multiple 3D systems (e.g. packages, which can include system-in-package and package-on-package structures).

FIG. 7 is a schematic cross-sectional side view illustration of a 3D system with mid-layer interposer 112 with removed bulk layer in accordance with embodiments. As described above with regard to FIG. 6, when thinning the bulk layer 111, in the embodiment illustrated in FIG. 7 the bulk layer 111 may be completely removed. This may be optionally followed by formation of the back side routing layer 105, and then the first package level 120. The back side routing layer 105 is not required, and the front side routing layer 115 may include a single the metal wiring layer with one or more dielectric layers, multiple the metal wiring layers and dielectric layers, or only vias extending through one or more dielectric layers and optionally landing pads. In such an embodiment, through vias 118 can be avoided, reducing cost as well as potential hindrances to through via density. In this manner, vertical connections through the mid-layer interposer 112 can be through line/via patterning common in CMOS BEOL manufacturing and/or thin film RDL techniques.

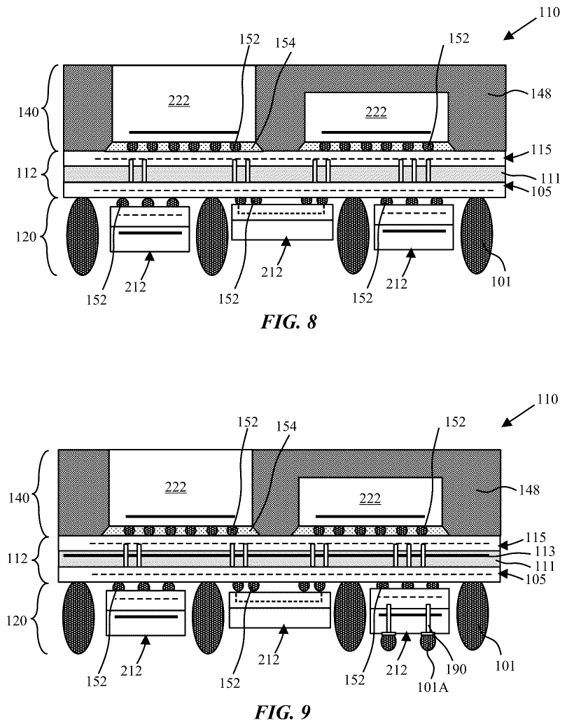

Referring now to FIGS. 8-9, schematic cross-sectional side view illustrations are provided of 3D systems with mid-layer interposers with a non-encapsulated first package level in accordance with embodiments. FIGS. 8-9 are substantially similar, with one difference being the mid-layer interposer of FIG. 9 includes active or passive devices 113, while the mid-layer interposer of FIG. 8 is primarily for routing purposes, though may include thermal and mechanical functionality. The 3D systems of FIGS. 8-9 may be manufactured similarly as previous embodiments, with a difference being that after mounting of the first-level dies 212 an encapsulation operation is not performed, and instead tall solder bumps 101, or instead pillars with solder tips are located laterally adjacent to the first level dies 212. Such a configuration may reduce fabrication costs, and processing time. Additionally, the first-level dies 212 may optionally not include through vias. This can add wiring constraint, though also further reduce cost. Further, one of more first-level dies 212 (e.g. chiplet, silicon interconnect, stack) may support through silicon vias (TSVs) and under bump metallurgy (UBM) landing pads, and a solder bump 101A (flip chip or ball grid array). This flip chip or ball grid array solder bump may be smaller in height than a regular solder bump 101 to accommodate the first-level die 212 height. The silicon interconnect may be a chiplet and may be purely passive, or active, and may additionally include passive components such as capacitors, inductors, etc. Furthermore, the silicon interconnect may be a monolithic die, or stacked die (stacked chiplet) structure.

The mid-layer interposer in accordance with embodiments can provide mechanical, thermal, and routing integrity to the 3D systems. In some embodiments, the integration of more metal wiring layers within the mid-layer interposer can support mechanical integrity, wiring fanout and complex wiring requirements. In some instances, the mid-layer interposer can provide die-to-die wiring connection. The dies within the 3D systems can also provide die-to-die connection, which can reduce the requirement for number of metal layers in the mid-layer interposer, as well as wiring line width/spacing, and even dielectric material requirements.

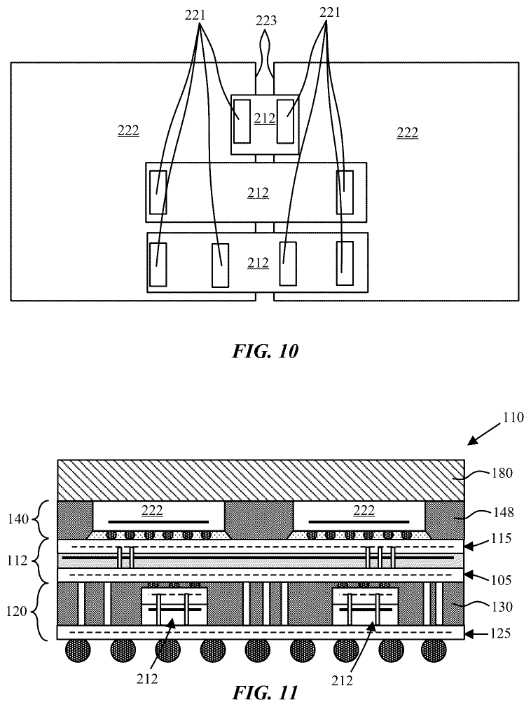

FIG. 10 is a schematic top layout view illustration of a 3D system with die-to-die routing passing through a first-level die 212 in accordance with an embodiment. As shown, the first-level dies 212, such as silicon interconnect, can facilitate the lateral interconnection between input/output regions 221 of the second-level dies 222, which can be located along the die edges 223, as well as further interior such as within the die core (logic) regions. Each silicon interconnect may be a chiplet and may be purely passive, or active, and may additionally include passive components such capacitors, inductors, etc. Furthermore, the silicon interconnect may be a monolithic die, or stacked die (stacked chiplet) structure.

The mid-layer interposer 112 in accordance with embodiments may still include die-to-die routing, with potential limitations on through via 118 density in the mid-layer interposer 112. Where a die in another die level is used to provide the lateral portion of die-to-die connection the through via 118 density can be increased and/or the number of metal wiring layers in the mid-layer interposer 112 can be decreased. By way of example, for an ultra fine μbump pitch of 12×12 μm, a through via density percent can range from 1%-5% of the mid-layer interposer 112 area, with through via diameter ranging between 1-3 μm, and mid-layer interposer thickness ranging between 10-30 μm. For an ultra fine μbump pitch of 6×6 μm, a through via density percent can range from 1%-8% of the mid-layer interposer 112 area, with through via diameter ranging between 0.5-2 μm, and mid-layer interposer thickness ranging between 5-20 μm.

The 3D systems in accordance with embodiments may be further designed to manage thermal dissipation from the dies, and in particular the high performance dies within the second package level.

FIG. 11 is a schematic top layout view illustration of a 3D system with a thermal lid in accordance with an embodiment. As shown, a thermal lid 180 can be attached to the second package level 140, and in particular to one or more of the second-level dies 222 to dissipate/absorb heat generated by the dies. The thermal lid 180 may be a carrier substrate, for example, or another layer of the same size as the singulated 3D system. The thermal lid 180 can be formed of a variety of thermally conductive materials, including metal, aluminum nitride, silicon, etc. In an embodiment, the thermal lid is formed of a silicon substrate, which has sufficient thermal conductivity to draw heat away from the dies and a coefficient of thermal expansion (CTE) compatible with chip materials. The thermal lid can be bonded to the underlying structure with a bonding layer, which can be a thin oxide, metal, solder, etc. In an embodiment the thermal lid is bonded to the underlying structure with oxide-oxide bonding of bonding layers. In another embodiment, thermal lid is bonded to the underlying structure with metal bonding such as with transient liquid phase (TLP) bonding where one or more intermetallic compounds are formed by interdiffusion of bonding layers. The thermal lid 180 can be singulated with the 3D system as part of the reconstitution fabrication sequence (e.g. when also functioning as a carrier substrate during the reconstitution sequence) or even applied later as a separate component.

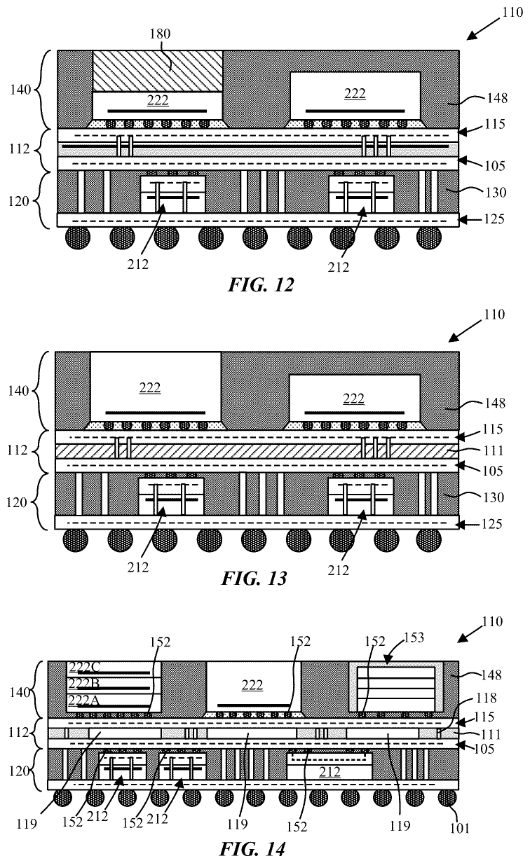

The thermal lid 180 can also be bonded to specific dies, such as a second-level die 222 as shown in FIG. 12 that may generate a greater amount of heat, such as the high performance dies. In this manner, the thermal benefit can be obtained with reduced fabrication/material cost. Thermal assistance can also be integrated into the mid-layer interposer 112. FIG. 13 is a schematic top layout view illustration of a 3D system with a thermally enhanced mid-layer interposer in accordance with an embodiment. For example, the bulk layer 111 of the mid-layer interposer 112 may be formed of a material with higher thermal conductivity than silicon. For example, silicon carbide, a composite, or other material can be used as the bulk layer 111 and processed similarly as previously described. Silicon carbide may additionally provide adequate thermal expansion matching with silicon, while also providing heat spreading for the 3D system.

Materials selection for the mid-layer interposer, and bulk layer 111 in particular may be based on considerations other than thermal. For example, a glass bulk layer 111 may be utilized to provide lower parasitic through vias 118. Low CTE polymers (e.g. 4 or less) may also be employed, as well as composites (e.g. including silica) can be employed to tune mechanical, thermal, and electrical properties.

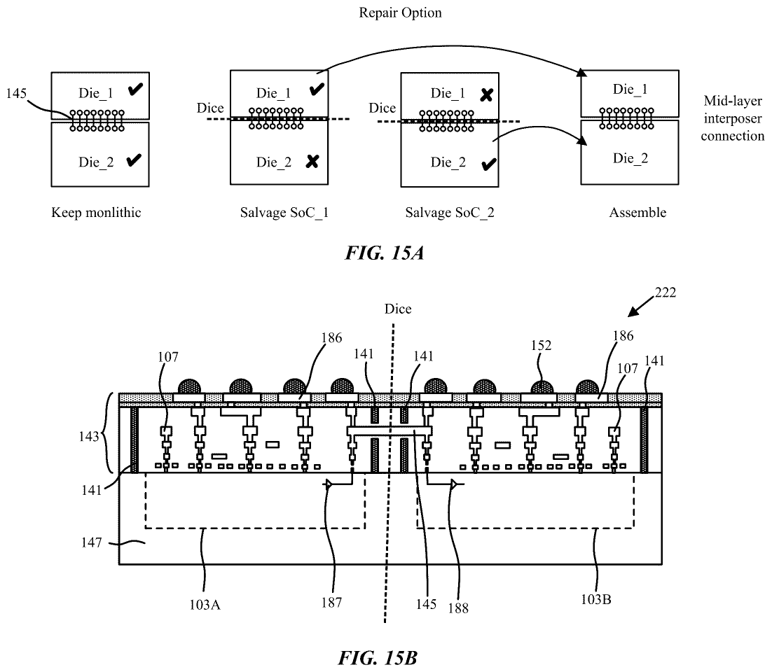

Integration of the mid-layer interposer 112 into the reconstitution fabrication sequence and diced 3D systems may also be compatible with monolithic die set repair. FIG. 15A is a schematic flow diagram illustrating a repair option process flow in accordance with an embodiment. FIG. 15B is a schematic cross-sectional side view illustration of a monolithic die set with pre-formed die-to-die routing in accordance with an embodiment. Referring to FIGS. 15A-15B, die sets of 2 or more dies may be tied together with die-to-die routing 145 formed in the BEOL build-up structure 143 formed over a bulk layer 147, such as silicon substrate. The die-to-die routing 145 may be formed in the metal wiring layers 107 of the BEOL build-up structure 143, and may optionally extend through or over a metallic seal structure 141 (e.g. seal ring) that surrounds the die areas 103A, 103B of the adjacent die sets. As shown, the dies may each include devices such as transceivers 187 and receivers 188 for communication across the die-to-die routing 145.

FIG. 14 is a schematic cross-sectional side view illustration of a 3D system with a reconstituted mid-layer interposer 112 including discrete, integrated components 119 embedded in a gap fill material in accordance with an embodiment. For example, the integrated components 119 can be integrated passive devices, optical components/structure, etc. In such an embodiment the bulk layer 111 may be a gap fill material such as molding compound (organic), oxide, oxynitride, silicon, or other inorganic material(s). Such an organization may balance function and cost of the system assembly. As shown, the top side routing layer 115 and back side routing layer 105 are optional. Through vias 118 (e.g. through silicon vias, through glass vias, through dielectric vias, through mold vias, etc.) may additionally extend through the bulk layer/gap fill material to support electrical routing. As previously described, top side routing layer 115, and back side routing layer 105 are optional, and electrical connection can be from the various package levels can be made directly to the integrated components 119.

Referring to FIG. 15A, the die sets across a wafer can be tested prior to dicing of the die sets to ensure functionality within designed ranges. Where a die is found to be defective, the adjacent dies of the die set can be scribed along the dice line between the dies, which may also proceed through pre-existing die-to-die wiring, that is now exposed along a die edge. In such a repair sequence, the operable dies that have been singulated may then be integrated with the mid-layer interposer 112 in accordance with embodiments.

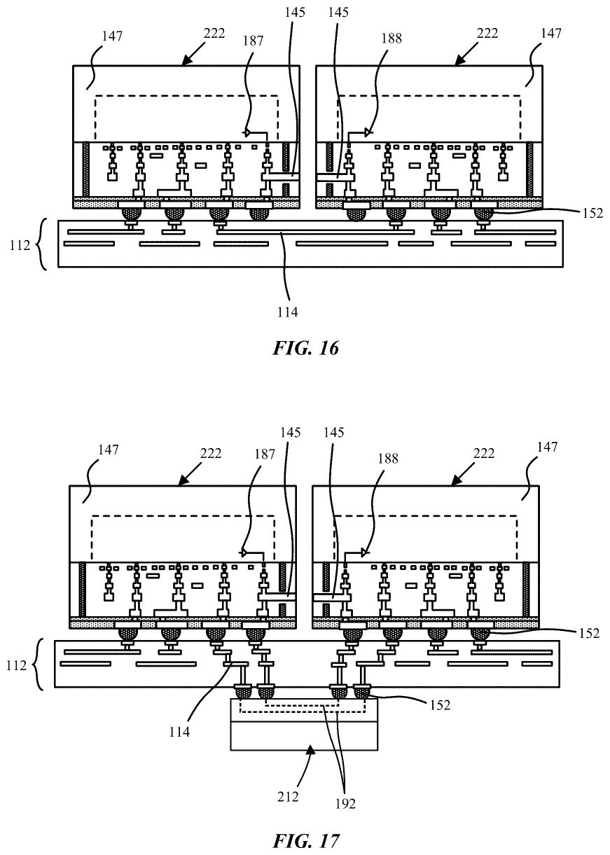

FIGS. 16-17 are schematic cross-sectional side view illustration of a scribed die set with pre-formed and scribed die-to-die routing mounted on a mid-layer interposer in accordance with an embodiment. In the embodiment illustrated in FIG. 16, the dies, or illustrated second-level dies 222, can be flip chip mounted onto landing pads of the mid-layer interposer 112 using a plurality of ultra fine μbumps 152. The second-level dies 222 can optionally then be connected with die-to-die wiring in the metal wiring layers 114 of the mid-layer interposer 112. In the embodiment illustrated in FIG. 22, the second-level dies 222 can be connected with die-to-die wiring 192 within a first-level die 212, such as a silicon interconnect/chiplet, that is bonded to the bottom side of the mid-layer interposer 112, and connected to the second-level dies through one or more metal wiring layers 114. The silicon interconnect may be a chiplet and may be purely passive, or active, and may additionally include passive components such capacitors, inductors, etc. Furthermore, the silicon interconnect may be a monolithic die, or stacked die (stacked chiplet) structure. It is to be appreciated that the embodiments illustrated in FIGS. 16-17 are compatible with previously illustrated and described embodiments, and certain structural features are not shown in order to more clearly illustrate the die-to-die connections.

Up until this point various 3D systems and assembly techniques have been described in which ultra fine μbumping techniques can be used to achieve fine bump pitch in multiple package levels. The various 3D systems and assembly techniques are also compatible with electromagnetic field communication structures such as capacitive, magnetic, or photonic coupling to communicate across dielectric layers, or even thin metal layers. Photonic coupling may include photonic waveguides or photonic wires, for example, as well as electrical-to-optical (EO) converters and optical-to-electrical (OE) converters. Such electromagnetic field communication structures can also be integrated with ultra fine μbumping. An EO converter may include conversion electronics and any suitable optical transmitter such as laser, light emitting diode, or other light source, modulator, etc. An OE converter may include an optical receiver such as a photodetector (avalanche photodiode, p-i-n photodiode, etc.) and conversion electronics. One or more optical repeater structures may additionally be included in the optical paths to receive, amplify, and then re-transmit the optical signals. One example is an optical amplifier (e.g. semiconductor optical amplifier). Other repeaters may be electrical/optical that can be integrated into active silicon connected to the optical paths with a variety of features such as logic, flops, cache, memory compressors and decompressors, controllers, local processing elements, etc. The OE/EO converters can also include optical mutliplexers, demultiplexers.

The dies described herein may additionally include an assembly of different components, can be heterogenous, and be hierarchically arranged. For example, a die may include a separately formed layer(s) of an optical converter, or multiple attached components.

The optical paths produced by the waveguides or photonic wires may be rigid or flexible. In an exemplary embodiment, waveguides are formed of a suitable material, such as oxide or nitride, that is readily integrated into semiconductor device fabrication and packaging. For example, the waveguides may be integrated into the top side routing layer 115 and/or back side routing layer 105 of a mid-layer interposer 112. Vertical photonic communication, such as across ultra fine μbumped surfaces, can be further negotiated using optical vias, grating couplers, mirrors, prisms, or additional waveguides or photonic wire bonds.

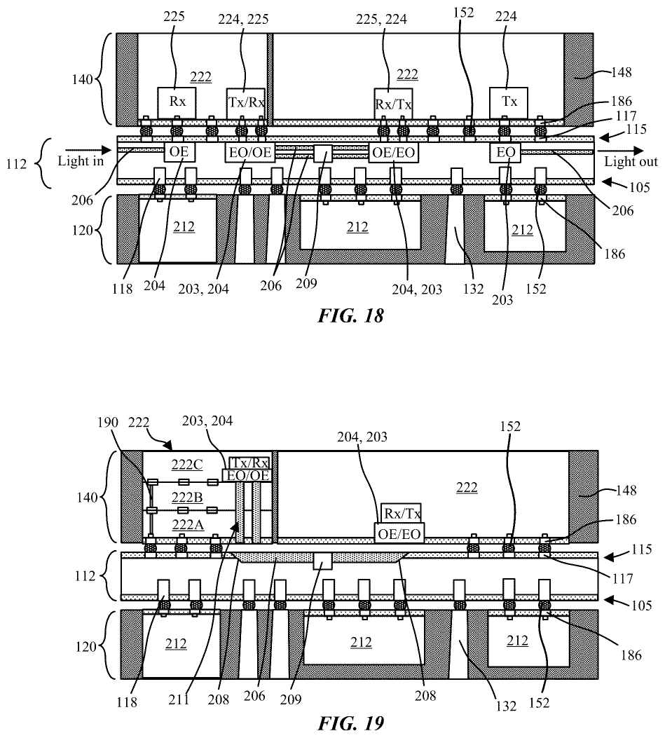

Referring now to FIGS. 18-23 schematic cross-sectional side view illustrations are provided of exemplary 3D systems within optical interconnects in accordance with embodiments. The 3D system structures may correspond to the 3D system structures previously described herein, and as such, the illustrational detail is focused on the optical interconnect structures rather than common shared features previously described herein.

The particular embodiment illustrated in FIG. 18 may be similar to those illustrated and described with regard to FIGS. 4-5 for example, including a first package level 120 with one or more first-level dies 212 (e.g. any of silicon interconnect 122, moderate power die 124, LSIO die 126, cache die 128 or combination thereof) and a second package level 140 with one or more second-level dies 222 (e.g. any of high power die 142, high power die 144, HSIO die 146, memory die stack 153). It is to be appreciated that the first-level dies 212 and second level dies 222 are not limited to these specific examples. In the interest of not obscuring the subject matter of the optical paths, the illustrational detail is focused on the optical interconnect structures rather than common shared features previously described herein, which may be included.

In the particular embodiment illustrated an optical path is entirely contained within a mid-layer interposer 112 and connects a plurality of second-level dies 222. Similarly, the optical path could connect a plurality of first-level dies 212. In the exemplary illustration, various second-level dies 222 can include transceivers (Tx) 224 and receivers (Rx) 225 that may be in electrical connection with landing pads 186 of the second-level dies 222. Similar to previously described process flows, the one or more second-level dies 222 can be encapsulated in an encapsulation layer 148, with landing pads 186 aligned with landing pads 117 of the mid-layer interposer 112. The first-level dies 212 can also ultra fine μbumped to the back side routing layer 105 and/or through vias 118 of the mid-layer interposer 112. In the illustrated embodiment, the Tx 224/Rx 225 and Rx 225/Tx 224 are in electrical communication with optical converters in the mid-layer interposer 112, and more specifically electrical-to-optical (EO) converters 203 and optical-to-electrical (OE) converters 204. One or more optical interconnects 206 (e.g. waveguide, photonic wire), for example within the top side routing layer 115, may then connect adjacent optical converters to provide an optical path. Such an optical path may provide short communication, or long reach communication, and is not limited to die-edge connections, and may provide core-to-core connection between dies, or opposite edges. A variety of configurations are possible. In some embodiments, one or more repeaters 209 may be included along the optical path and be connected to the optical interconnect 206 to receive, amplify, and then re-transmit the optical signals. In an exemplary configuration a Tx 224 may be electrically connected to EO converter 203, which converts the electrical signal to an optical signal which is then transferred across the optical interconnect 206 (e.g. waveguide, photonic wire) to an OE converter 204, which transmits the optical signal to an electrical signal, which in turn is in electrical connection with the Rx 225 in a separate second-level die 222. Complementary systems are also in place for reverse communication between the second-level dies 222.

It is to be appreciated that while die-to-die connection is illustrated and described as being through the mid-layer interposer 112 to connect multiple second-level dies 222, that the die-to-die connection may be between multiple first-level dies 212. Furthermore, while the optical communication path is described with a waveguide as the optical interconnect 206, this may be replaced with another suitable optical interconnect such as a photonic wire that is wire bonded to the corresponding EO and OE converters.

Also illustrated in FIG. 18 are optical paths that can go into out from the mid-layer interposer 112, and 3D system. As shown, the mid-layer interposer can include an exposed optical interconnect 206 along an edge of the mid-layer interposer to receive light from outside of the 3D system or to transmit light out from the 3D system. While this is shown with regard to a lateral side edge, this could also be top or bottom. For example, the light may be transmitted from outside of the 3D system, and received by an optical interconnect 206 (e.g. waveguide, photonic wire) which is connected to an OE converter 204. The OE converter 204 may optionally be connected to a receiver 225 in any of the dies mounted to the mid-layer interposer 112, or to a receiver within the mid-layer interposer. A complementary structure for transceiver 224, EO converter 203 and optical interconnect 206 is also shown for transmission of light out from the mid-layer interposer 112, and 3D system. The arrangements of transceiver/receiver and converters may be between any combination of die(s) and/or mid-layer interposer.

Referring now to FIG. 19 a schematic cross-sectional side view illustration is provided of a 3D system structure with optical interconnects similar to the structure of FIG. 18. Like FIG. 18, FIG. 19 resembles that of FIG. 5. In the interest of not obscuring the subject matter of the optical paths, the illustrational detail is focused on the optical interconnect structures rather than common shared features previously described herein, which may be included. In the particular embodiments, the EO converters 203 and OE converters 204 may be located with the second-level dies 222 while the optical interconnects 206 (waveguides or photonic wires) are located in the mid-layer interposer 112. Furthermore, optical vias 211 may optionally extend through any or all layers between the converters and the optical interconnects 206 to facilitate the optical path. For example, optical vias may be filled with a transparent material of specific refractive index.

As shown, in accordance with the various embodiments described herein the dies may include a plurality of three dimensional (3D) stacked dies (e.g. 222A, 222B, 222C, etc.). While three dies are illustrated, it is to be appreciated this is exemplary, and embodiments may include two or more stacked dies. In accordance with embodiments, the optical vias 211 may extend through one or more of the dies, which may also be electrically connected with TSVs, contact pads, etc. In the illustrated embodiment, the optical path (through one or more optical vis 211 for example) may proceed through one or more of the stacked dies. Each die (or chiplet) may be similar to a die as defined herein, and the 3D stack may be fusion bonded, TCB, hybrid bonded, or bonded with ultra fine μbumps. In this manner, the optical path (and optical interconnect) may extend to any die within the 3D stack. It is to be appreciated that the illustrated example of multiple stacked dies is exemplary, and embodiments do not require multiple stacked dies within a die.

The optical path may connect all of the dies (222A, 222B, 222C) or some permutations (e.g., 222A and 222C, or 222C as shown in the drawing). Further the optical paths may be shared, or separate, depending on EO/OE and waveguides and wavelengths. Referring briefly to FIG. 24, a schematic cross-sectional side view illustration is provided of a second-level die 222 including multiple EO converters 203, OE converters 204, and optical vias 211 in accordance with an embodiment. In this manner, each die may include a corresponding transceiver and/or receiver, and converter. The illustrated optical vias 211 may be singular as shown, or multiples. The optical vias 211 may be bi-directional (for optical transmission and reception) or single directional. An array of optical vias 211 may be included to support communication with different wavelengths and/or to different dies. For example, the optical vias 211 can connect dies 222B and 222C, as well as connect one or more dies to the mid-layer interposer 112 or to one or more first-level dies.

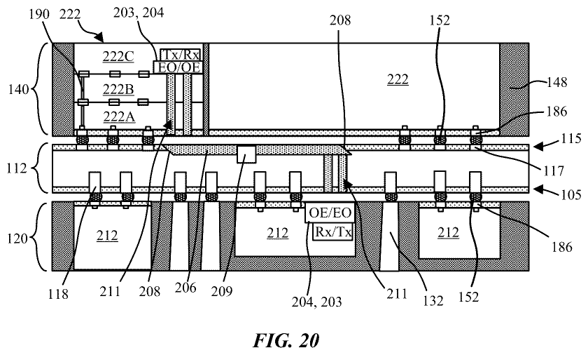

One or more mirrors 208, diffraction grating coupler, prism, etc. may also facilitate connecting the vertical optical path with the optical interconnect 206. In this manner, the optical paths may travel from the EO converters 203 through the optional optical vias 211 (or other intermediate dielectric/insulating layer), through the optical interconnect 206 (waveguide or photonic wire), back through optional optical vias (or other intermediate dielectric/insulating layer) and to the OE converters 204 located in a separate die. Referring to FIG. 20, one or more optical vias 211 can also extend at least partially through the mid-layer interposer 112 to connect to one or more first-level dies 212. For example, an optical via 211 can extend through any of the bulk layer 111, top side routing layer 115 and back side routing layer 105. The optical path may connect a second-level die 222 to a first-level die 212 in the illustrated embodiment.

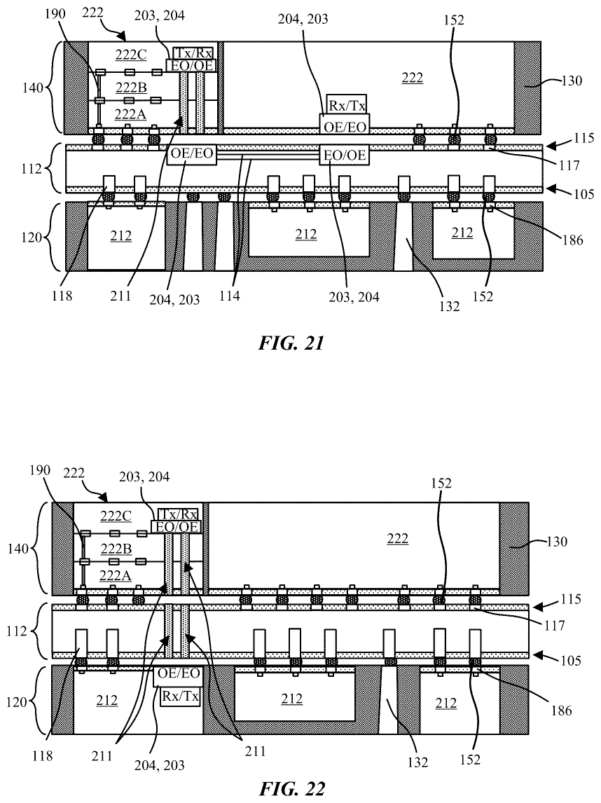

Referring now to FIGS. 21-22 schematic cross-sectional side view illustrations are provided of 3D systems with optical interconnects similar to the structures of FIGS. 18-19, with different locations of the EO and OE converters. Like FIGS. 18-19, FIGS. 21-22 resemble those of FIGS. 4-5. In the interest of not obscuring the subject matter of the optical paths, the illustrational detail is focused on the optical interconnect structures rather than common shared features previously described herein, which may be included. In such embodiments the optical paths may be much shorter, effectively bridging the vertical distance between a package level and mid-layer interposer 112 as shown in FIG. 21 or between dies in different package levels as shown in FIG. 22. The optical paths may also extend through one or more dies 222A, 222B, 222C, etc. as previously described with regard to FIG. 19, and FIG. 24. In the embodiment illustrated in FIG. 22, the optical path may proceed through optical vias 211 extending completely through the mid-layer interposer 112.

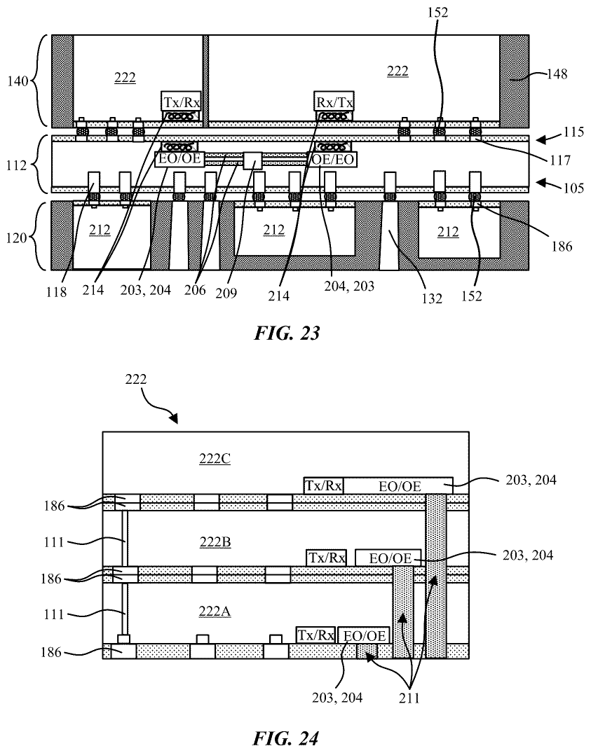

Referring now to FIG. 23 a schematic cross-sectional side view illustration is provided of a 3D system structure with optical interconnects similar to the structure of FIG. 18, with different connections between the dies and mid-layer interposer. Like FIG. 18, FIG. 23 resembles those of FIGS. 4-5. In the interest of not obscuring the subject matter of the optical paths, the illustrational detail is focused on the optical interconnect structures rather than common shared features previously described herein, which may be included. In such embodiments short range communication paths (e.g less than 100 μm (magnetic, and less than 1-μm capacitive coupled)) can be achieved with various electromagnetic field communication structures with capacitive coupling, magnetic coupling, optical coupling. For example, the electromagnetic field communication structures 214 can include coils or capacitors to facilitate coupling and may be vertically aligned. The electromagnetic field communication structures 214 can wireless communicate between the second-level dies 222 and mid-layer interposer 112. The electromagnetic field communication structures 214 within the mid-layer interposer 112 can further be connected to EO converters 203 and OE converters 204, with the optical interconnect 206 connecting the converters.

It is to be appreciated that while the embodiments of FIGS. 18-23 are illustrated as separate 3D system structures that the various optical interconnects can be combined. Furthermore, the optical interconnects of FIGS. 18-23 may also be combinable with metal wiring paths described herein. In addition, the dies within various package levels may include multiple 3D stacked dies.

The mid-layer interposers 112 in accordance with embodiments can include electrical routing, as well as passive device and/or active devices. In some embodiments the mid-layer interposers 112 can include banks of passive devices such as trench capacitors or MIM capacitors. However, it may not be suitable to connect all capacitors and capacitor banks for all applications, or in the case of defective devices. In accordance with embodiments, the mid-layer interposers can include customized routing and connectivity to the devices.

In the following description various mid-layer interposers 112 can be used for repair options. Specifically, the following description and illustrations may be used for decoupling capacitor repair. This concept can also be used for repair of various routing paths, memory block, circuit blocks, etc.

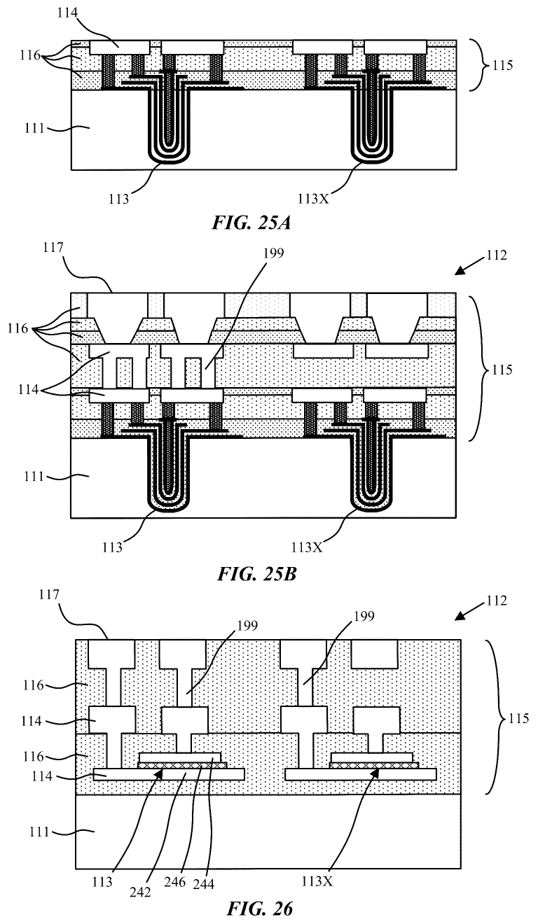

FIGS. 25A-25B are schematic cross-sectional side view illustrations of a sequence for testing and connecting a bank of deep trench capacitors within a mid-layer interposer in accordance with an embodiment. As shown in FIG. 25A the top side routing layer 115 (or back side routing layer 105) is partially fabricated including devices 113 (deep trench capacitors) as well as dielectric layers 116 and metal wiring layers 114. At this stage the devices can be tested in-line. Good devices 113 can be electrically connected with vias 199, while vias 199 may optionally not be formed to connect defective devices 113X (including passive devices such as MIM capacitors (planar or 3D) or trench capacitors, magnetic elements, or even active devices such as transistors) as shown in FIG. 25B. Thus, the mid-layer interposer may include a dielectric layer 116 within the top side routing layer 115 (or back side routing layer 105) where vias 199 are connected to only some of the devices 113. As such, the defective devices 113X may be left floating, or electrically isolated.

A similar embodiment is shown in FIG. 26, where the devices 113 are MIM capacitors include a lower terminal 242 (plate), upper terminal 244 (plate) and high dielectric constant dielectric material 246 therebetween. The lower terminal 242 and upper terminal 244 may be formed of the metal wiring layers 114. The dielectric material 246 may have a higher dielectric constant than the dielectric layers 116 forming the top side routing layer 115 (or back side routing layer 105).

Still referring to FIG. 26, a via 199 is optionally connected to one of the terminals for a defective device 113X. This may also be the case with the trench capacitors of FIG. 25B. For example, this may be a low power (Vss) connection. However, high power Vdd may not be connected to the defective device 113X with a via 199.

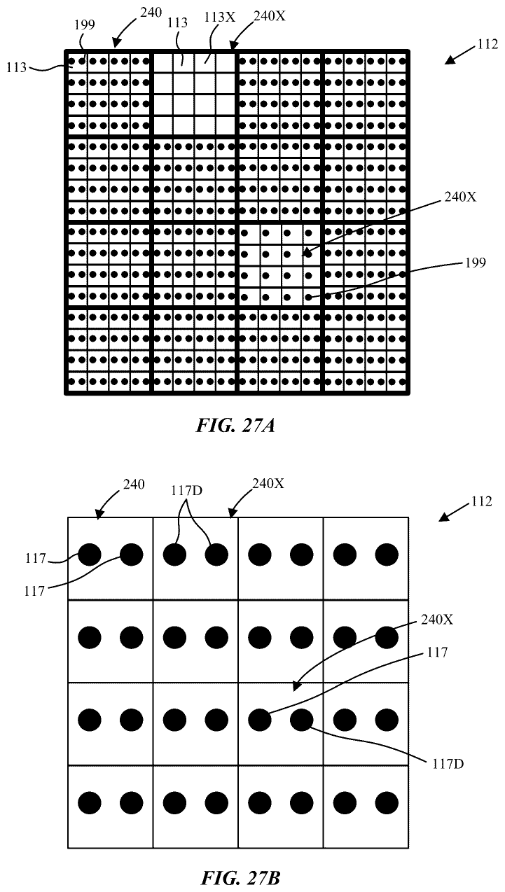

The programmable writing may be used to connect appropriate vias 199 or provide open wiring. While FIGS. 25A-25B and FIG. 26 are shown at the device scale, the programmable writing may be used to connect, or alternatively mask, entire banks of devices. FIG. 27A is a schematic top view illustration of a via 199 connections to devices 113 within a mid-layer interposer in accordance with an embodiment. As shown individual devices 113 can be arranged into groups of banks 240. Where a defective device 113X is determined, an entire masked bank 240X can be designated. For example, where a single defective device 113X is measured then the via 199 connections can be skipped for an entire associated masked bank 240X. Alternatively, measurements may not be so precise, and instead testing is performed at the bank level, and as such a defective bank may be measured which indicates one or more defective device 113X in the masked bank 240X. In an embodiment, the mid-layer interposer 112 may include a plurality of banks 240, including one or more masked banks 240X including an array of capacitors that are either not electrically connected, or incompletely connected, such as with only Vss via 199 connections.

FIG. 27B is a schematic top view illustration of landing pad connections to capacitor banks in accordance with an embodiment. Thus, FIG. 27B illustrates the mid-layer interposer 112 further along in the fabrication sequence. As shown, landing pads 117 may still be formed for each bank 240 and masked bank 240X. This can facilitate further metal-metal bonding. For example, the two illustrated landing pads 117 can be for low power (Vss) and high power (Vdd) connection. Masked banks may include one or more dummy landing pads 117D that are not connected to the capacitors. For example, the dummy landing pads can be for both Vss and Vdd connections, or just for the Vdd connection in the exemplary embodiments. Embodiments are not limited to two landing pads 117, and this is merely exemplary. In accordance with embodiments the dummy landing pads 117D for a masked bank 240X may overlay an array of capacitors that are not electrically connected or incompletely connected to the corresponding landing pads 117 of the masked bank.

In utilizing the various aspects of the embodiments, it would become apparent to one skilled in the art that combinations or variations of the above embodiments are possible for forming a 3D system with mid-layer interposer. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A three-dimensional (3D) system comprising:
a mid-layer interposer;
a first package level underneath the mid-layer interposer, the first package level including a first first-level die bonded to the mid-layer interposer with a first plurality of ultra fine micro bumps (μbumps);
a second package level over the mid-layer interposer, the second package level including a first second-level die bonded to the mid-layer interposer with a second plurality of ultra fine micro μbumps.

2. The 3D system of claim 1, wherein the second plurality of ultra fine μbumps have a pitch of less than 15 μm.

3. The 3D system of claim 2, wherein the second plurality of ultra fine μbumps have a pitch of less than 10 μm.

4. The 3D system of claim 2, further comprising a set of through vias extending at least partially through the mid-layer interposer.

5. The 3D system of claim 2, wherein the interposer includes a bulk layer and a top side routing layer, and the first second-level die is bonded to the top side routing layer.

6. The 3D system of claim 5, wherein the interposer includes a back side routing layer, and the first first-level die is bonded to the back side routing layer.

7. The 3D system of claim 6, wherein the mid-layer interposer includes an array of capacitors, an array of magnet elements, or both.

8. The 3D system of claim 6, wherein the mid-layer interposer includes active devices.

9. The 3D system of claim 5, wherein the bulk layer is formed of a material characterized by a higher thermal conductivity than silicon.

10. The 3D system of claim 5, wherein the bulk layer is glass.

11. The 3D system of claim 10, wherein the first first-level die is a passive component.

12. The 3D system of claim 10, wherein the first second-level die is a passive component.

13. The 3D system of claim 2, further comprising a second second-level die bonded to the mid-layer interposer with a third plurality of ultra fine micro μbumps.

14. The 3D system of claim 13, wherein the first first-level die includes a portion of a die-to-die routing path between the first second-level die and the second second-level die.

15. The 3D system of claim 13, wherein the mid-layer interposer includes a die-to-die routing path between the first second-level die and the second second-level die.

16. The 3D system of claim 15, wherein the die-to-die routing path comprises an optical path.

17. The 3D system of claim 16, wherein:
the mid-layer interposer includes an electrical-to-optical (EO) converter electrically connected with the first second-level die, and an optical-to-electrical (OE) converter electrically connected with the second second-level die; and
the EO converter is connected to a first electromagnetic field communication structure, and the first second-level die includes a second electromagnetic field communication structure.

18. The 3D system of claim 17, wherein the first electromagnetic field communication structure and the second electromagnetic field communication structure are vertically aligned, and the first electromagnetic field communication structure and the second electromagnetic field communication structure are coils or capacitors.

19. The 3D system of claim 13, wherein the first second-level die comprises a diced die-to-die routing path that terminates along a die edge of the first second-level die.

20. The 3D system of claim 13, wherein the second second-level die comprises multiple stacked dies.

21. The 3D system of claim 2, further comprising a second first-level die bonded to the mid-layer interposer with a third plurality of ultra fine micro μbumps, wherein the first second-level die includes a portion of a die-to-die routing path between the first first-level die and the second first-level die.

22. The 3D system of claim 2, further comprising a thermal lid attached to the second package level.

23. The 3D system of claim 2:
wherein the first-level die or the mid-layer interposer includes an optical-to-electrical (OE) converter, and the second-level die includes an electrical-to-optical (EO) converter; and
further comprising an optical via that optically connects the EO converter with the OE converter.

24. The 3D system of claim 23, wherein:
the first-level die includes the OE converter; and
the optical via extends through the mid-layer interposer vertically between the first-level die and the second-level die.

25. The 3D system of claim 23, wherein the second-level die includes a plurality of stacked dies, and the optical via extends through one or more of the plurality of stacked dies.

26. The 3D system of claim 25, wherein the mid-layer interposer includes the OE converter.

27. The 3D system of claim 2, wherein the mid-layer interposer includes an electrical-to-optical (EO) converter electrically connected with the first second-level die, an optical-to-electrical (OE) converter electrically connected with the second second-level die, and an optical interconnect that connects the EO converter and the OE converter.

28. The 3D system of claim 27, wherein the optical interconnect comprises a waveguide or photonic wire.

29. The 3D system of claim 2, wherein:
the first second-level die includes an electrical-to-optical (EO) converter, and the second second-level die includes an optical-to-electrical (OE) converter; and
the mid-layer interposer includes an optical interconnect that is optically connected with the EO converter and the OE converter.

30. The 3D system of claim 2, wherein second plurality of ultra fine micro μbumps is characterized by a finer pitch than the first plurality of ultra fine micro μbumps.

31. The 3D system of claim 2, wherein the mid-layer interposer includes one or more integrated components embedded within a gap fill material.

32. The 3D system of claim 2, wherein the mid-layer interposer includes a plurality of banks of devices, wherein the plurality of banks of devices includes a masked bank with a dummy landing pad not connected to devices in the masked bank.

33. The 3D system of claim 2, wherein the mid-layer interposer includes an exposed optical interconnect along an edge of the mid-layer interposer to receive light from outside of the 3D system or to transmit light out from the 3D system.
